(19) United States
(12) Patent Application Publication
(10) Pub. No.: US 2024/0213166 A1
(43) Pub. Date: Jun. 27, 2024

(54) SEMICONDUCTOR PACKAGE AND METHOD FOR FABRICATING THE SAME

(71) Applicant: Samsung Electronics Co., Ltd., Suwon-si (KR)

(72) Inventors: Se-Ho YOU, Suwon-si (KR); Byeong Uk JEON, Suwon-si (KR)

(21) Appl. No.: 18/377,569

(22) Filed: Oct. 6, 2023

(30) Foreign Application Priority Data
Dec. 22, 2022 (KR) 10-2022-0181472

(51) Int. Cl. H01L 23/538; H01L 23/00; H01L 23/31; H01L 25/065

(52) U.S. Cl. CPC H01L 23/5381; H01L 23/3185; H01L 24/16; H01L 24/17; H01L 25/0655; H01L 2224/16235; H01L 2224/16258; H01L 2224/17153

(57) ABSTRACT

A semiconductor package including a package substrate, a bridge structure stacked on the package substrate, a first molding member surrounding a side surface of the bridge structure, a trace pattern extending along an upper surface of the bridge structure and an upper surface of the first molding member, a via pattern penetrating through the first molding member and electrically connecting the package substrate and the trace pattern to each other, and a first semiconductor chip and a second semiconductor chip each stacked on the upper surface of the first molding member and electrically connected to each other by the bridge structure. The first semiconductor chip and the second semiconductor chip are arranged along a first direction parallel to an upper surface of the package substrate and the trace pattern extends in the first direction and is electrically connected to at least one of the first semiconductor chip and the second semiconductor chip.

### CROSS-REFERENCE TO RELATED APPLICATION

This application claims priority from Korean Patent Application No. 10-2022-0181472 filed on Dec. 22, 2022 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor package and a method for fabricating the same, and more particularly, to a semiconductor package including a bridge structure and a method for fabricating the same.

### 2. Description of the Related Art

In accordance with the rapid development of the electronic industry and the needs of users, electronic devices are becoming more miniaturized, lightweight, and multifunctional, and semiconductor packages used in the electrical devices are also required to be miniaturized, lightweight, and multifunctional. To this end, by integrating two or more types of semiconductor chips into one semiconductor package, it is possible to realize high capacity and multifunctional purposes of the semiconductor package while significantly reducing a size of the semiconductor package.

### SUMMARY

Aspects of the present disclosure provide a semiconductor package including a bridge structure and easily supplying power to semiconductor chips.

Aspects of the present disclosure also provide a method for manufacturing a semiconductor package including a bridge structure and a trace pattern for supplying power to semiconductor chips.

However, embodiments of the inventive concept are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a semiconductor package comprising a package substrate, a bridge structure stacked on the package substrate, a first molding member surrounding a side surface of the bridge structure, a trace pattern extending along an upper surface of the bridge structure and an upper surface of the first molding member, a first via pattern penetrating through the first molding member and electrically connecting the package substrate and the trace pattern to each other, a first through via penetrating through the first molding member and spaced apart from a first side surface of the bridge structure, a second through via penetrating through the first molding member and spaced apart from a second side surface of the bridge structure, a first semiconductor chip stacked on the trace pattern and the first through via, a second semiconductor chip stacked on the trace pattern and the second through via, a first chip connection terminal electrically connecting the first through via and the first semiconductor chip to each other, a second chip connection terminal electrically connecting the second through via and the second semiconductor chip to each other, a first trace connection terminal electrically connecting the trace pattern and the first semiconductor chip to each other, a second trace connection terminal electrically connecting the trace pattern and the second semiconductor chip to each other, and a second molding member covering at least a portion of the first semiconductor chip and at least a portion of the second semiconductor chip on the package substrate.

According to another aspect of the present disclosure, there is provided a semiconductor package comprising a package substrate, a bridge structure stacked on the package substrate, a first molding member surrounding a side surface of the bridge structure, a trace pattern extending along an upper surface of the bridge structure and an upper surface of the first molding member, a via pattern penetrating through the first molding member and electrically connecting the package substrate and the trace pattern to each other, a first semiconductor chip and a second semiconductor chip each stacked on the upper surface of the first molding member and electrically connected to each other by the bridge structure, a first through via penetrating through the first molding member and electrically connecting the package substrate and the first semiconductor chip to each other, a second through via penetrating through the first molding member and electrically connecting the package substrate and the second semiconductor chip to each other, a first trace connection terminal electrically connecting the trace pattern and the first semiconductor chip to each other, and a second trace connection terminal electrically connecting the trace pattern and the second semiconductor chip to each other.

According to still another aspect of the present disclosure, there is provided a semiconductor package comprising a package substrate, a bridge structure stacked on the package substrate, a first molding member surrounding a side surface of the bridge structure on the package substrate, a trace pattern extending along an upper surface of the bridge structure and an upper surface of the first molding member, a via pattern penetrating through the first molding member and electrically connecting the package substrate and the trace pattern to each other, and a first semiconductor chip and a second semiconductor chip each stacked on the upper surface of the first molding member and electrically connected to each other by the bridge structure, wherein the first semiconductor chip and the second semiconductor chip are arranged along a first direction parallel to an upper surface of the package substrate, and the trace pattern extends in the first direction and is electrically connected to at least one of the first semiconductor chip and the second semiconductor chip.

### BRIEF DESCRIPTION OF THE DRAWINGS

The above and other aspects and features of the present disclosure will become more apparent by describing in detail example embodiments thereof with reference to the attached drawings, in which:

FIG. 1 is an illustrative layout view for describing a semiconductor package according to some example embodiments;

FIG. 2 is a schematic cross-sectional view taken along line A-A of FIG. 1 according to some example embodiments;

FIG. 3 is a schematic cross-sectional view taken along line B-B of FIG. 1 according to some example embodiments;

FIGS. 4 to 6 are various schematic cross-sectional views taken along line A-A in FIG. 1 according to some example embodiments;

FIG. 7 is another illustrative layout view for describing a semiconductor package according to some example embodiments;

FIG. 8 is a schematic cross-sectional view taken along line C-C of FIG. 7;

FIG. 9 is another illustrative layout view for describing a semiconductor package according to some example embodiments;

FIG. 10 is a schematic cross-sectional view taken along line D-D of FIG. 9;

FIGS. 11 to 13 are various illustrative layout views for describing a semiconductor package according to some example embodiments;

FIGS. 14 to 19 are intermediate step views for describing a method for fabricating a semiconductor package according to some example embodiments.

### DETAILED DESCRIPTION OF THE EMBODIMENTS

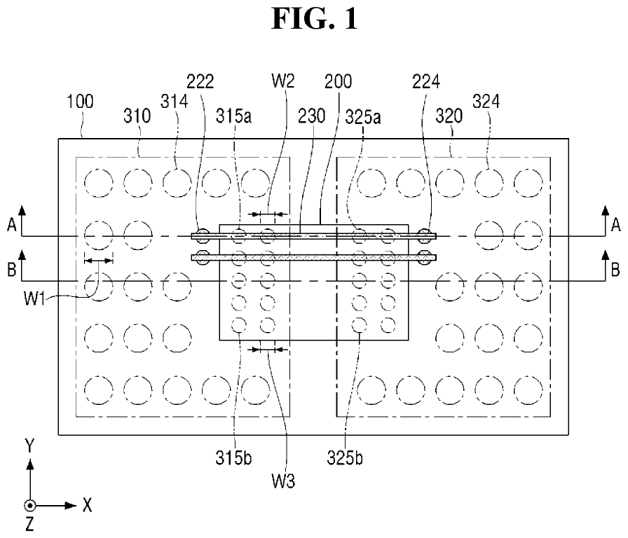

Hereinafter, semiconductor packages according to example embodiments will be described with reference to FIGS. 1 to 13.

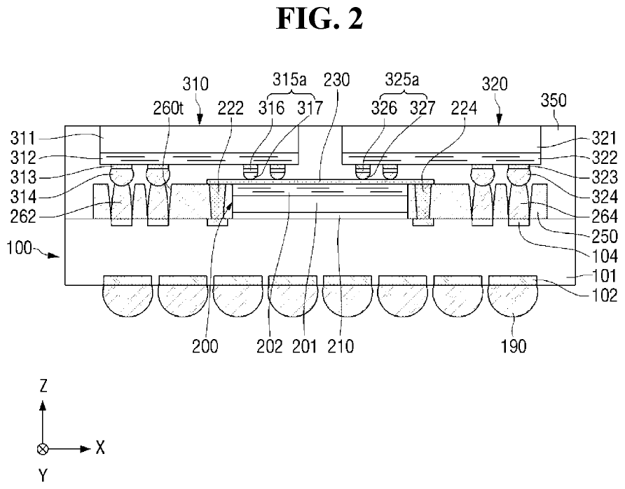

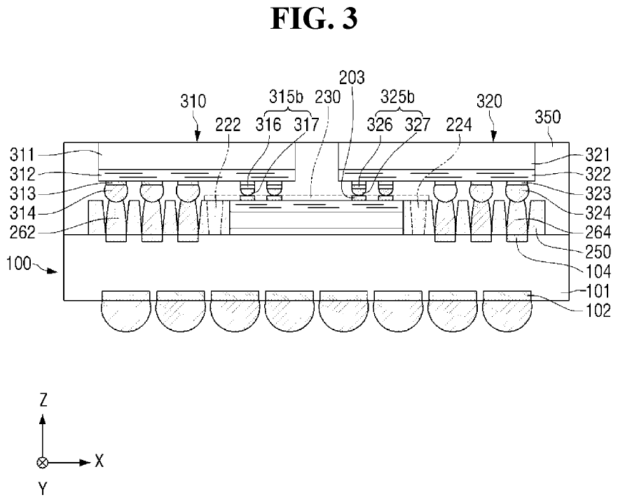

FIG. 1 is an illustrative layout view for describing a semiconductor package according to some example embodiments. FIG. 2 is a schematic cross-sectional view taken along line A-A of FIG. 1. FIG. 3 is a schematic cross-sectional view taken along line B-B of FIG. 1.

Referring to FIGS. 1 to 3, a semiconductor package according to some example embodiments includes a package substrate 100, a substrate bump 190, a bridge structure 200 (also described herein as a bridge), a first via pattern 222, a second via pattern 224, a trace pattern 230, a first molding member 250, a first through via 262, a second through via 264, a first semiconductor chip 310, a first chip connection member 314, a first trace connection member 315a, a first bridge connection member 315b, a second semiconductor chip 320, a second chip connection member 324, a second trace connection member 325a, a second bridge connection member 325b, and a second molding member 350.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Additionally, when an element is referred to as being “electrically connected” an electric current is able to pass to or from element by way of the connection. Similarly, when an element electrically connects two or more elements an electrical current is able to pass between the two or more elements by traversing the element electrically connecting the two or more elements.

The package substrate 100 may be a substrate for a semiconductor package. As an example, the package substrate 100 may be a printed circuit board (PCB). The package substrate 100 may include a lower surface and an upper surface that are opposite to each other.

The package substrate 100 may include an insulating core 101, a first substrate pad 102, and a second substrate pad 104. In the following description various items described herein, such as pads, may be described in the singular, though they may be provided in plural, as can be seen, for example, in the figures. For example, FIG. 2 shows a plurality of substrate pads on a lower surface of the substrate 100 and a plurality of substrate pads on an upper surface of the substrate 100. Additionally, ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim). Each of the first substrate pad 102 and the second substrate pad 104 may be used to electrically connect the package substrate 100 to other components. For example, the first substrate pad 102 may be exposed and/or accessible from a lower surface of the insulating core 101 to electrically connect the package substrate 100 to a lower component, and the second substrate pad 104 may be exposed and/or accessible from an upper surface of the insulating core 101 to electrically connect the package substrate 100 to an upper component. Each of the first substrate pad 102 and the second substrate pad 104 may be formed of and/or include, for example, a metal material such as copper (Cu) or aluminum (Al), but each of the substrate pads are not limited thereto.

Although not illustrated, wiring patterns for electrically connecting the first substrate pad 102 and the second substrate pad 104 to each other may be formed in or provided in the insulating core 101. FIGS. 1 to 3 illustrate the insulating core 101 as a single layer for simplicity of illustration, but it will be appreciated that the insulating core 101 may comprise multiple layers. For example, the insulating core 101 may be configured as multiple layers and multiple layers of wiring patterns may be formed or otherwise provided within the insulating core.

The package substrate 100 may be mounted on a main board of an electronic device. For example, the substrate bump 190 may be electrically connected to the first substrate pad 102 and electrically connected to the main board of the electronic device. The package substrate 100 may be mounted on the main board of the electronic device through the substrate bump 190 which may also physically couple the package substrate to the main board of the electronic device. The substrate bump 190 may be a component of a ball grid array (BGA) for electrically connecting the package substrate 100 to another device, but embodiments of package substrates are not limited to those having BGAs.

The substrate bump 190 may be, for example, a solder bump, but embodiments are not limited thereto. The substrate bump 190 may have various shapes such as a land, a ball, a pin, or a pillar. The number, spacing, arrangement, and the like of the substrate bumps 190 are not limited to those illustrated and may vary according to designs.

The bridge structure 200 may be stacked or located on the upper surface of the package substrate 100. In some example embodiments, the bridge structure 200 may be a bridge chip. For example, the bridge structure 200 may include a bridge substrate 201 and a bridge wiring structure 202. The bridge wiring structure 200 may also be referred to as a bridge wiring layer.

The bridge substrate 201 may be a semiconductor substrate such as a silicon substrate or may also be an organic substrate including an insulating polymer or the like. The bridge wiring structure 202 may be formed on or located on the bridge substrate 201. The bridge wiring structure 202 may be multilayered and include multiple wiring patterns and insulating layers for insulating portions of the wiring patterns from each other. Herein, the surface of the bridge substrate 201 on which the bridge wiring structure 202 is formed or located may also be referred to as a front side of the bridge substrate 201. Conversely, the surface of the bridge substrate 201 opposite to the front side of the bridge substrate 201 may be referred to as a back side of the bridge substrate 201. In some embodiments, the bridge structure 200 does not include integrated circuits on the bridge substrate 201. In other embodiments, the bridge structure 200 includes at least one integrated circuit on the bridge substrate 201.

The bridge structure 200 may include a bridge pad 203. The bridge pad 203 may be used to electrically connect the bridge structure 200 to other components. For example, the bridge pad 203 may be electrically connected to the bridge wiring structure 202 and may be exposed or accessible from an upper surface of the bridge wiring structure 202.

In some example embodiments, the back side of the bridge substrate 201 may face the package substrate 100. For example, the bridge structure 200 may be orientated such that bridge substrate 201 is located between the bridge wiring structure 202 and the package substrate 100. For example, the bridge substrate 201 and the bridge wiring 202 may be sequentially stacked on the upper surface of the package substrate 100.

In some example embodiments, an adhesive film 210 may be interposed between the package substrate 100 and the bridge structure 200. The bridge structure 200 may be attached to the upper surface of the package substrate 100 through the adhesive film 210. The adhesive film 210 may be formed of and/or include, for example, a die attach film (DAF), a wafer tape, or a stacked form thereof. However, this is only an example, and the material constituting the adhesive film 210 is not limited to these examples as long as it attaches the bridge structure 200 to the upper surface of the package substrate 100.

The first molding member 250 may be formed on or provided on the upper surface of the package substrate 100. The first molding member 250 may surround a side surface of the bridge structure 200. For example, the first molding member 250 may cover at least a portion of the upper surface of the package substrate 100 and at least a portion of the side surface of the bridge structure 200. The first molding member 250 may contact side surfaces of the bridge structure 200 and portions of the upper surface of the package substrate 100. In addition, the first molding member 250 may leave the upper surface of the bridge structure 200 exposed and/or accessible. In some example embodiments, an upper surface of the first molding member 250 may be disposed on the same plane as (e.g., coplanar) with the upper surface of the bridge structure 200. The first molding member 250 may completely cover the side surface of the bridge structure 200.

The first molding member 250 may be described as a first molding layer and be formed of and/or include, for example, an insulating polymer material such as an epoxy molding compound (EMC), but is not limited thereto.

The first via pattern 222 and the second via pattern 224 may be disposed to the side of the bridge structure 200 and may be offset from the side surface. The first via pattern 222 and the second via pattern 224 may respectively penetrate through the first molding member 250 and be electrically connected to the package substrate 100. For example, each of the first via pattern 222 and the second via pattern 224 may extend in a third direction (e.g., the Z direction as shown in FIG. 2) crossing through the first molding member 250 to the upper surface of the package substrate 100 and be electrically connected to the second substrate pad 104. Each of the first via pattern 222 and the second via pattern 224 may be formed of and/or include a conductive material such as copper (Cu), aluminum (Al), silver (Ag), tin (Sn), gold (Au), nickel (Ni), lead (Pb), titanium (Ti), or an alloy thereof, but is not limited thereto. In some example embodiments, each of the first via pattern 222 and the second via pattern 224 may be a conductive pattern formed by spraying and curing conductive ink. Each of the first via pattern 222 and the second via pattern 224 may include a plurality of conductive vias, also described as conductive through vias. Alternatively, each described “via pattern” may refer to a single conductive via.

In some example embodiments, the first via pattern 222 may be disposed to one side surface of the bridge structure 200 and the second via pattern 224 may be disposed to a different (e.g., opposite) side surface of the bridge structure 200. For example, the first via pattern 222, the bridge structure 200, and the second via pattern 224 may be sequentially arranged, with intervening components such as the first molding member 250, along a first direction (e.g., the X direction as shown in FIG. 2) parallel to the upper surface of the package substrate 100.

In some example embodiments, a width of each conductive via of the first via pattern 222 and the second via pattern 224 may decrease as a distance from the upper surface of the package substrate 100 decreases. This may be due to characteristics of an etching process performed on the first molding member 250 to form the first via pattern 222 and the second via pattern 224.

The trace pattern 230 may be formed or disposed on (e.g., at the surface of) the bridge structure 200 and the first molding member 250. The trace pattern 230 may include at least one trace (e.g., wiring trace) that spans the bridge structure 200 and/or include at least one sub-trace that does not span the bridge structure 200. The trace pattern 230 may extend along the upper surface of the bridge structure 200 and the upper surface of the first molding member 250. At least one trace of the trace pattern 230 may be electrically connected to at least one of the first via pattern 222 and the second via pattern 224. For example, the trace pattern 230 may extend in the first direction X to cross the bridge structure 200. The first via pattern 222 may be electrically connected to a trace at one end of the trace pattern 230 and the second via pattern 224 may be electrically connected to the trace at the other end of the trace pattern 230. A trace of the trace pattern 230 may electrically connect the first via pattern 222 and the second via pattern 224 to each other. In some embodiments, a via pattern may electrically connect with a trace through contact between the via pattern and the trace.

In some example embodiments, the trace pattern 230 may include at least one trace extending in a straight line along the first direction X.

A trace of the trace pattern 230 may be formed of and/or include a conductive material such as copper (Cu), aluminum (Al), silver (Ag), tin (Sn), gold (Au), nickel (Ni), lead (Pb), titanium (Ti), or an alloy thereof, but is not limited thereto.

In some example embodiments, a plurality of traces that form a trace pattern 230 may be formed on the bridge structure 200 and the first molding member 250. The traces may be arranged in the trace pattern 230 along a second direction (e.g., spaced at an interval along the Y axis as shown in FIG. 2) that is parallel to the upper surface of the package substrate 100 and intersects the first direction X. The trace pattern 230 may extend in the first direction X. The number, spacing, arrangement, and the like of the traces are not limited to those illustrated and may vary according to designs. In addition, the traces may have different shapes other than those illustrated and may differ from one another within a trace pattern. In one embodiment, each trace may be connected to a corresponding first via from the first via pattern 222 (e.g., a first conductive via) and corresponding second via from the second via pattern 224 (e.g., a second conductive via).

In some example embodiments, portions or all of the traces of the trace pattern 230 may be formed by a trace-on-mold process. For example, the trace pattern 230 may be a conductive pattern formed by spraying and curing conductive ink on the upper surface of the bridge structure 200 and the upper surface of the first molding member 250.

In the embodiment illustrated in FIG. 3 it appears that a thickness of the trace pattern 230 is the same as that of the bridge pad 203, but this is only for simplicity of illustration. The thickness of the trace pattern 230 may also be different from that of the bridge pad 203 and in some embodiments, some bridge pads 203 may have the same thickness as some traces of trace pattern 230 while other bridge pads 203 may have a different thickness.

In some example embodiments, at least a portion of the trace pattern 230 may be electrically isolated from the bridge structure 200. For example, the trace pattern 230 may extend along an upper surface of the insulating layer of the bridge wiring structure 202. In some example embodiments, the trace pattern 230 may be electrically insulated from the electrical components of the bridge structure 200.

In some other example embodiments, the trace pattern 230 may also be electrically connected to the bridge structure 200. For example, at least some traces of the trace pattern 230 may be electrically connected to some of a plurality of bridge pads 203.

The first through via 262 and the second through via 264 may be disposed on the side of the bridge structure 200 (e.g., spaced from the side surface). The first through via 262 and the second through via 264 may respectively penetrate through the first molding member 250 and be electrically connected to the package substrate 100. For example, a first mold through hole 260t extending in the third direction Z within the first molding member 250 may expose the second substrate pad 104. Although described as a single element, the first mold element may include a plurality of mold through holes each of which could be referred to as a first mold through hole 260t. For example, FIG. 2 includes 4 mold through holes. The first through via 262 and the second through via 264 may each be formed or disposed in a respective first mold through hole 260t and electrically connected to a respective second substrate pad 104. Each of the first through via 262 and the second through via 265 may be formed of and/or include a conductive material such as copper (Cu), aluminum (Al), silver (Ag), tin (Sn), gold (Au), nickel (Ni), lead (Pb), titanium (Ti), or an alloy thereof, but is not limited thereto.

In some example embodiments, a width of the first mold through hole 260t may decrease as a distance from the upper surface of the package substrate 100 decreases. This may be due to characteristics of an etching process performed on the first molding member 250 to form the first mold through hole 260t.

In some example embodiments, the first via pattern 222 and the second via pattern 224 may be conductive patterns closest to (nearest to) the side surface of the bridge structure 200. For example, the first via pattern 222 may be closer to the bridge structure 200 than the first through via 262, and the second via pattern 224 may be closer to the bridge structure 200 than the second through via 264.

The first semiconductor chip 310 and the second semiconductor chip 320 may be stacked on the upper surface of the bridge structure 200 and the upper surface of the first molding member 250. Each of the first semiconductor chip 310 and the second semiconductor chip 320 may overlap the bridge structure 200 and the first molding member 250 in the third direction Z. In addition, at least one of the first semiconductor chip 310 and the second semiconductor chip 320 may overlap the trace pattern 230 in the third direction Z. As an example, the first semiconductor chip 310 and the second semiconductor chip 320 may be arranged along the first direction X to be horizontally separated from each other and at the same vertical height above the package substrate 100. The trace pattern 230 extends in the first direction X, so that one end thereof may overlap the first semiconductor chip 310 and the other end thereof may overlap the second semiconductor chip 320.

Each of the first semiconductor chip 310 and the second semiconductor chip 320 may be an integrated circuit (IC) in which hundreds to millions of semiconductor elements are integrated into one chip. For example, each of the first semiconductor chip 310 and the second semiconductor chip 320 may be an application processor (AP) chip such as a microprocessor and a microcontroller, a logic chip such as a central processing unit (CPU), a graphic processing unit (GPU), a modem, an application-specific IC (ASIC), and a field programmable gate array (FPGA), a volatile memory chip such as a dynamic random access memory (DRAM) or a static random access memory (SRAM), a non-volatile memory chip such as a phase-change random access memory (PRAM), a magnetic random access memory (MRAM), a ferroelectric random access memory (FeRAM), and a resistive random access memory (RRAM), a flash memory, or a high bandwidth memory (HBM), or may include a combination thereof.

In some example embodiments, the first semiconductor chip 310 and the second semiconductor chip 320 may be different types of semiconductor chips. As an example, the first semiconductor chip 310 may be an application processor chip or a logic chip, and the second semiconductor chip 320 may be a memory chip.

The first semiconductor chip 310 may include a first semiconductor substrate 311 and a first wiring structure 312, and the second semiconductor chip 320 may include a second semiconductor substrate 321 and a second wiring structure 322. A wiring structure may also be referred to as a wiring layer.

Each of the first semiconductor substrate 311 and the second semiconductor substrate 321 may be a bulk silicon or silicon-on-insulator (SOI) substrate. In other embodiments, each of the first semiconductor substrate 311 and the second semiconductor substrate 321 may also be a silicon substrate, or may also be formed from and/or include another material, for example, silicon germanium, silicon germanium on insulator (SGOI), indium antimonide, a lead tellurium compound, indium arsenide, indium phosphide, gallium arsenide, or gallium antimonide. Alternatively, each of the first semiconductor substrate 311 and the second semiconductor substrate 321 may have an epitaxial layer formed on a base substrate.

The first wiring structure 312 may be formed or provided on the first semiconductor substrate 311, and the second wiring structure 322 may be formed or provided on the second semiconductor substrate 321. The first wiring structure 312 and the second wiring structure 322 may each include multilayered wiring patterns and insulating layers for insulating at least a portion of the multilayered wiring patterns from each other.

A plurality of circuit elements may be formed on each of the first semiconductor substrate 311 and the second semiconductor substrate 321. The first wiring structure 312 may be electrically connected to circuit elements of the plurality of circuit elements on the first semiconductor substrate 311, and the second wiring structure 322 may be electrically connected to circuit elements of the plurality of circuit elements on the second semiconductor substrate 321. Herein, a surface of the first semiconductor substrate 311 on which the first wiring structure 312 is formed and a surface of the second semiconductor substrate 321 on which the second wiring structure 322 is formed may also be each referred to as a front side of the respective semiconductor substrate. Conversely, a surface of the first semiconductor substrate 311 opposite to the front side of the first semiconductor substrate 311 and a surface of the second semiconductor substrate 321 opposite to the front side of the second semiconductor substrate 321 may be each referred to as a back side of the respective semiconductor substrate.

In some example embodiments, the first semiconductor chip 310 and the second semiconductor chip 320 may be respectively stacked on the bridge structure 200 and the first molding member 250 and secured in a face-to-face (F2F) bonding manner. That is, the front side of the first semiconductor substrate 311 and the front side of the second semiconductor substrate 321 may each face the front side of the bridge substrate 201 (e.g., the side on which the wiring structure 202 is formed).

The first semiconductor chip 310 may include a first chip pad 313. The first chip pad 313 may be used to electrically connect the first semiconductor chip 310 to other components. For example, the first chip pad 313 may be electrically connected to the first wiring structure 312 and may be exposed and/or accessible from the lower surface of the first wiring structure 312.

The second semiconductor chip 320 may include a second chip pad 323. The second chip pad 323 may be used to electrically connect the second semiconductor chip 320 to other components. For example, the second chip pad 323 may be electrically connected to the second wiring structure 322 and may be exposed and/or accessible from the lower surface of the second wiring structure 322.

Each of the first chip pad 313 and the second chip pad 323 may be formed of and/or include a conductive material such as copper (Cu), aluminum (Al), silver (Ag), tin (Sn), gold (Au), nickel (Ni), lead (Pb), titanium (Ti), or an alloy thereof, but is not limited thereto.

The first chip connection member 314 may be formed or provided on a lower surface of the first chip pad 313. The first chip connection member 314 may electrically connect the first through via 262 and the first chip pad 313 to each other. As a result, the first semiconductor chip 310 may be electrically connected to the package substrate 100 through the first through via 262 and the first chip connection member 314.

The second chip connection member 324 may be formed or provided on a lower surface of the second chip pad 323. The second chip connection member 324 may electrically connect the second through via 264 and the second chip pad 323 to each other. As a result, the second semiconductor chip 320 may be electrically connected to the package substrate 100 through the second through via 264 and the second chip connection member 324.

The various connection members discussed herein that connect to another device may be described as connection terminals. Each of the first chip connection member 314 and the second chip connection member 324 may be, for example, a solder bump, but chip connection members are not limited thereto. The number, spacing, arrangement, and the like of the first chip connection member 314 and the second chip connection member 324, respectively, are not limited to those illustrated, and may vary according to designs.

The first bridge connection member 315b may be formed or provided on the lower surface of the first chip pad 313. As illustrated in FIGS. 1 and 3, the first bridge connection member 315b may electrically connect the bridge pad 203 and the first chip pad 313 to each other. As a result, the first semiconductor chip 310 may be electrically connected to the bridge structure 200 through the first bridge connection member 315b.

The second bridge connection member 325b may be formed or provided on the lower surface of the second chip pad 323. As illustrated in FIGS. 1 and 3, the second bridge connection member 325b may electrically connect the bridge pad 203 and the second chip pad 323 to each other. As a result, the second semiconductor chip 320 may be electrically connected to the bridge structure 200 through the second bridge connection member 325b.

The first semiconductor chip 310 and the second semiconductor chip 320 may be electrically connected to each other through the bridge structure 200. For example, the bridge wiring structure 202 connected to the bridge pad 203 may electrically connect the first semiconductor chip 310 and the second semiconductor chip 320 to each other by way of the first bridge connection member 315b and second bridge connection member 325b. The first semiconductor chip 310 and the second semiconductor chip 320 may communicate data with one another through the bridge wiring structure 202.

Each of the first bridge connection member 315b and the second bridge connection member 325b may be, for example, a solder bump, but bridge connection members are not limited thereto. The number, spacing, arrangement, and the like of the first bridge connection members 315b and the second bridge connection members 325b, respectively, are not limited to those illustrated, and may vary according to designs.

The first trace connection member 315a may be formed or provided on the lower surface of the first chip pad 313. As illustrated in FIGS. 1 and 2, the first trace connection member 315a may electrically connect a trace of the trace pattern 230 and the first chip pad 313 to each other. As a result, the first semiconductor chip 310 may be electrically connected to the trace of the trace pattern 230 through the first trace connection member 315a. In addition, the first semiconductor chip 310 may be electrically connected to the package substrate 100 through the first via pattern 222 and the trace of the trace pattern 230.

The second trace connection member 325a may be formed or provided on the lower surface of the second chip pad 323. As illustrated in FIGS. 1 and 2, the second trace connection member 325a may electrically connect a trace of the trace pattern 230 and the second chip pad 323 to each other. As a result, the second semiconductor chip 320 may be electrically connected to the trace of the trace pattern 230 through the second trace connection member 325a. In addition, the second semiconductor chip 320 may be electrically connected to the package substrate 100 through the second via pattern 224 and the trace of the trace pattern 230.

Each of the first trace connection member 315a and the second trace connection member 325a may be, for example, a solder bump, but trace connection members are not limited thereto. The number, spacing, arrangement, and the like of the first trace connection members 315a and the second trace connection members 325a, respectively, are not limited to those illustrated, and may vary according to designs.

At least one trace of the trace pattern 230 may be electrically connected to at least one of the first semiconductor chip 310 and the second semiconductor chip 320. In the example embodiments of FIG. 2, it is illustrated that at least one trace of the trace pattern 230 is electrically connected to both the first semiconductor chip 310 and the second semiconductor chip 320, but in other example embodiments the trace pattern 230 is not electrically connected to both the first semiconductor chip 310 and the second semiconductor chip 320. As another example, one of the first trace connection member 315a and the second trace connection member 325a may also be omitted. That is, the trace pattern 230 may also be electrically connected to one of the first semiconductor chip 310 and the second semiconductor chip 320. Some or all traces of trace pattern 230 may be formed on the bridge structure 200 to electrically connect one or more of first and second semiconductor chips 310 and 320 to package substrate 100, while being electrically insulated and isolated from any other electrical components of the bridge structure 200.

In some example embodiments, at least one of the first semiconductor chip 310 and the second semiconductor chip 320 may receive a power supply voltage by way of at least one trace of the trace pattern 230. For example, the power supply voltage may be provided to the first semiconductor chip 310 through the package substrate 100, the first via pattern 222, and a trace of the trace pattern 230. Alternatively, the power supply voltage may be provided to the second semiconductor chip 320 through the package substrate 100, the second via pattern 224, and a trace of the trace pattern 230. In some example embodiments, the first semiconductor chip 310 and the second semiconductor chip 320 may receive the same power supply voltage from a single trace of the trace pattern 230. For example, the power supply voltage may be supplied to a substrate bump 190 configured to distribute the power supply voltage to second substrate pads 104 connected to the first via pattern 222 and the second via pattern 224 respectively. The first via pattern 222 and the second via pattern 224 may be connected to circuitry in the respective first semiconductor chip 310 and second semiconductor chip 320 configured to receive a power supply voltage (e.g., a constant voltage when power is being supplied).

In some example embodiments, the sizes of the first trace connection member 315a and the second trace connection member 325a may be smaller than the sizes of the first chip connection member 314 and the second chip connection member 324. For example, as illustrated in FIG. 1, a width W2 of the first trace connection member 315a may be smaller than a width W1 of the first chip connection member 314.

In some example embodiments, the sizes of the first bridge connection member 315b and the second bridge connection member 325b may be smaller than the sizes of the first chip connection member 314 and the second chip connection member 324. For example, as illustrated in FIG. 1, a width W3 of the first bridge connection member 315b may be smaller than the width W1 of the first chip connection member 314.

The figures illustrate the width W2 of the first trace connection member 315a as appearing to be the same as the width W3 of the first bridge connection member 315b, but this is only an example. The width W2 of the first trace connection member 315a may also be different from the width W3 of the first bridge connection member 315b.

In some example embodiments, each of the first trace connection member 315a, the second trace connection member 325a, the first bridge connection member 315b, and the second bridge connection member 325b may be a micro bump including a low melting point metal formed from and/or including, for example, tin (Sn) and a tin (Sn) alloy.

In some example embodiments, each of the first trace connection member 315a and the first bridge connection member 315b may include a first conductive pillar 316 and a first solder cap 317, and each of the second trace connection member 325a and the second bridge connection member 325b may include a second conductive pillar 326 and a second solder cap 327. The first conductive pillar 316 may be a pillared structure electrically connected to the first chip pad 313. The first solder cap 317 may be formed or provided on the first conductive pillar 316 (e.g., on a lower surface of the first conductive pillar 316). The second conductive pillar 326 may be a pillared structure electrically connected to the second chip pad 323. The second solder cap 327 may be formed or provided on the second conductive pillar 326 (e.g., on a lower surface of the second conductive pillar 326).

Each of the first conductive pillar 316 and the second conductive pillar 326 may be formed from and/or include a material having high electrical conductivity, such as copper (Cu), but is not limited thereto. Each of the first solder cap 317 and the second solder cap 327 may be formed from and/or include a solder material, for example, at least one of lead (Pb), tin (Sn), indium (In), bismuth (Bi), antimony (Sb), silver (Ag), and an alloy thereof.

The second molding member 350 may be formed or provided on the upper surface of the package substrate 100. The second molding member 350 may cover at least portions of the first molding member 250, the first semiconductor chip 310, and the second semiconductor chip 320. For example, the second molding member 350 may cover the upper surface of the package substrate 100, the side and upper surfaces of the first molding member 250, the side surface of the first semiconductor chip 310, and the side surface of the second semiconductor chip 320. In addition, the second molding member 350 may also fill an area between the first molding member 250 and the first semiconductor chip 310 and an area between the first molding member 250 and the second semiconductor chip 320. The figures illustrate that the second molding member 350 exposes the upper surface of the first semiconductor chip 310 and the upper surface of the second semiconductor chip 320, but this is only an example, and in other example embodiments the second molding member 350 may also cover the upper surfaces of the first semiconductor chip 310 and the second semiconductor chip 320.

The second molding member 350 may be a second molding layer, also described as an encapsulant, and may be formed from and/or include, for example, an insulating polymer material such as an epoxy molding compound (EMC), but is not limited thereto. The first molding member 250 and the second molding member 350 may also include the same material or different materials.

Due to the adoption of high bandwidth memory (HBM), an interposer market for connecting different semiconductor chips to each other is growing. In addition, as an interposer technology, an embedded multi-die interconnect bridge (EMIB) technology that embeds a bridge chip in a printed circuit board (PCB) or the like may be employed.

However, in the existing EMIB technology, if the bridge chip connects the semiconductor chips in a face-to-face (F2F) bonding manner, there may be a problem supplying power from the package substrate on which the semiconductor chips and/or the bridge chips are mounted. For example, when the bridge chip is interposed between the package substrate and the semiconductor chips, a transfer path of power supplied from the package substrate to the semiconductor chips may be designed to avoid connecting to circuitry in the bridge chip. In order to avoid the inefficiency of the transfer path of power, a through via (e.g., through silicon via (TSV)) penetrating through the bridge chip without connecting to other circuitry in the bridge chip may be considered. However, additional process steps and costs required to form the through via degrade productivity of the semiconductor package.

A semiconductor package according to some example embodiments avoids the issues described above and the efficiency of a transfer path of power may be improved by using a via pattern (e.g., the first via pattern 222 and/or the second via pattern 224) and the trace pattern 230. Specifically, as described above, since at least a portion of the trace pattern 230 may extend along the upper surface of the bridge structure 200, the transfer path of power may be provided in an area overlapping the bridge structure 200 in the third direction Z. In addition, the first via pattern 222 and/or the second via pattern 224 electrically connected to the trace pattern 230 may be disposed adjacent to the side surface of the bridge structure 200. Furthermore, as described above, since the traces of the trace pattern 230 may be formed by the trace-on-mold process, the transfer path of power may be provided with relatively simple process steps and low cost. As a result, even though the bridge structure 200 electrically connecting the first semiconductor chip 310 and the second semiconductor chip 320 to each other is provided, the semiconductor package may easily supply power to the first semiconductor chip 310 and/or the second semiconductor chip 320.

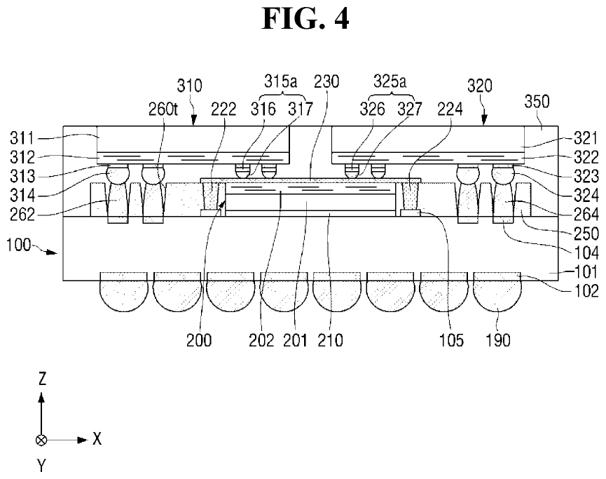

FIGS. 4 to 6 are various schematic cross-sectional views of additional example embodiments. The additional example embodiments share the same layout view of FIG. 1 with the example embodiments shown in FIGS. 2 and 3, but differences will be apparent in the cross-sectional views taken along line A-A in FIG. 1. For convenience of explanation, elements that are the same or significantly similar to those described above with reference to FIGS. 1 to 3 may be briefly described or omitted.

Referring to FIG. 4, the semiconductor package according to some example embodiments further includes a passive device 105.

The passive device 105 may be disposed on the upper surface of the package substrate 100. The passive device 105 may include an integrated passive device (IPD) in which a resistor, a capacitor, an inductor, or a combination thereof. In some embodiments, the passive device 105 may be integrated into the package substrate 100.

In some example embodiments, the passive device 105 may be electrically connected to the first via pattern 222 and/or the second via pattern 224. In some example embodiments, the first molding member 250 may cover the passive device 105. The first via pattern 222 and/or the second via pattern 224 may penetrate or pass through the first molding member 250 and be electrically connected to the passive device 105.

Although the figure illustrates that the passive device 105 is electrically connected to both the first via pattern 222 and the second via pattern 224, this is only an example, and in some embodiments the passive device 105 is not electrically connected at least one of the first via pattern 222 or the second via pattern 224. In addition, although the figure illustrates that the first through via 262 and the second through via 264 are not electrically connected to the passive device 105, this is also only an example, and in some embodiments the passive device 105 is electrically connected to at least one of the first through via 262 or the second through via 264.

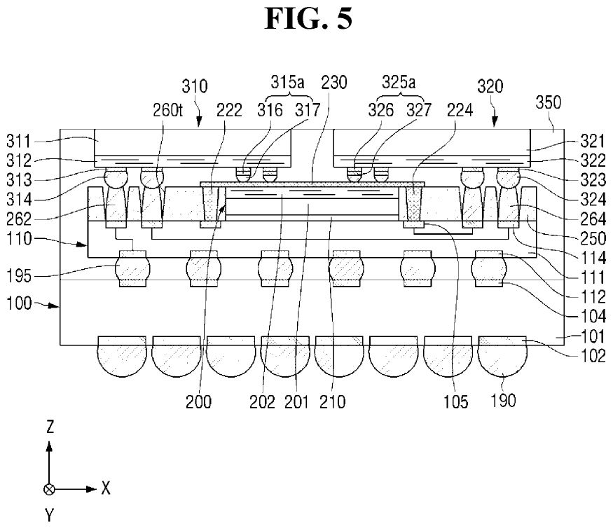

Referring to FIG. 5, the semiconductor package according to some example embodiments further includes an interposer 110.

The interposer 110 may be interposed between the package substrate 100 and the bridge structure 200 and between the package substrate 100 and the first molding member 250. The interposer 110 may be a silicon interposer or an organic interposer, but is not limited thereto.

The interposer 110 may include an interposer insulating layer 111, a first interposer pad 112, and a second interposer pad 114. Each of the first interposer pad 112 and the second interposer pad 114 may be used to electrically connect the interposer 110 to other components. For example, the first interposer pad 112 may be exposed and/or accessible from a lower surface of the interposer insulating layer 111, and the second interposer pad 114 may be exposed and/or accessible from an upper surface of the interposer insulating layer 111. Each of the first interposer pad 112 and the second interposer pad 114 may include, for example, a metal material such as copper (Cu) or aluminum (Al), but is not limited thereto.

Although not specifically illustrated, wiring patterns electrically connected to the first interposer pad 112 and/or the second interposer pad 114 may be formed or provided in the interposer insulating layer 111. The figure illustrates that the interposer insulating layer 111 is a single layer, but this is only for simplicity of illustration. For example, the interposer insulating layer 111 may be configured as multiple layers and multilayered wiring patterns may be formed therein.

The interposer 110 may be mounted on the package substrate 100. For example, interposer bumps 195 electrically connecting the second substrate pad 104 and the first interposer pad 112 to each other may be formed. The interposer 110 may be mounted on the package substrate 100 through the interposer bumps 195.

The bridge structure 200 may be stacked on an upper surface of the interposer 110. For example, the adhesive film 210 may be interposed between the interposer 110 and the bridge structure 200. The bridge structure 200 may be attached onto the interposer 110 by the adhesive film 210. In addition, the first molding member 250 may be formed on the upper surface of the interposer 110.

The interposer 110 may be electrically connected to the first through via 262 and/or the second through via 264. For example, the first through via 262 and/or the second through via 264 may be electrically connected to the second interposer pad 114. As a result, the interposer 110 may electrically connect the first semiconductor chip 310 and the second semiconductor chip 320 to the package substrate 100.

In some example embodiments, the interposer 110 may electrically connect the first semiconductor chip 310 and the second semiconductor chip 320 to each other. For example, the interposer 110 may electrically connect the first through via 262 and the second through via 264 to each other.

In some example embodiments, the interposer 110 may be electrically connected to the first via pattern 222 and/or the second via pattern 224. For example, the first via pattern 222 and/or the second via pattern 224 may be electrically connected to the second interposer pad 114. As a result, the interposer 110 may electrically connect the trace pattern 230 to the package substrate 100.

In some example embodiments, the interposer 110 may electrically connect the first semiconductor chip 310 and/or the second semiconductor chip 320 and the trace pattern 230 to each other. For example, the interposer 110 may electrically connect the second via pattern 224 and the second through via 264 to each other.

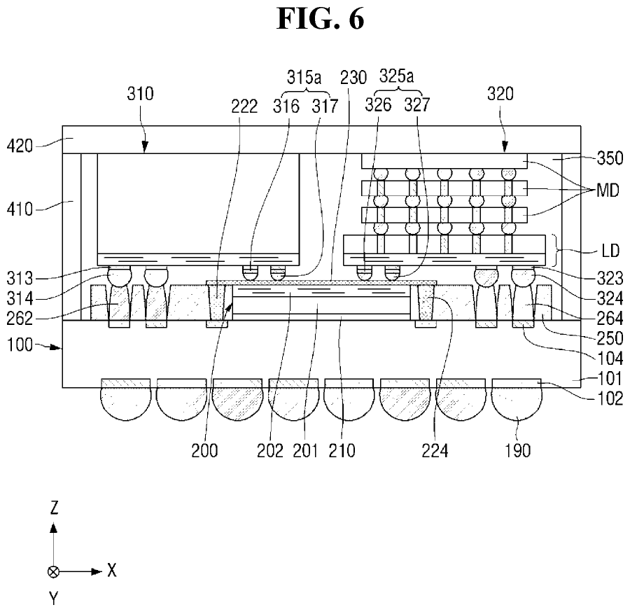

Referring to FIG. 6, a semiconductor package according to some example embodiments includes a stack memory.

For example, the first semiconductor chip 310 may be an application processor chip or a logic chip, and the second semiconductor chip 320 may be a stack memory such as high bandwidth memory (HBM). Such a stack memory may have a form in which a plurality of integrated circuits are stacked. The stacked integrated circuits may be electrically connected to each other through a through silicon via (TSV) or the like.

In some embodiments, the second semiconductor chip 320 may include a logic chip LD and a plurality of memory chips MD. The logic chip LD includes a serial-parallel conversion circuit and may be a buffer chip for controlling the plurality of memory chips MD. The logic chip LD may be, for example, a central processing unit (CPU) chip, a graphic processing unit (GPU) chip, or an application processor (AP) chip. The plurality of memory chips MD may be sequentially stacked on the logic chip LD. Each of the memory chips MD may be, for example, a DRAM chip, an SRAM chip, a flash memory chip, an EEPROM chip, a PRAM chip, an MRAM chip, or an RRAM chip. As an example, the memory chips MD may be HBM DRAM semiconductor chips.

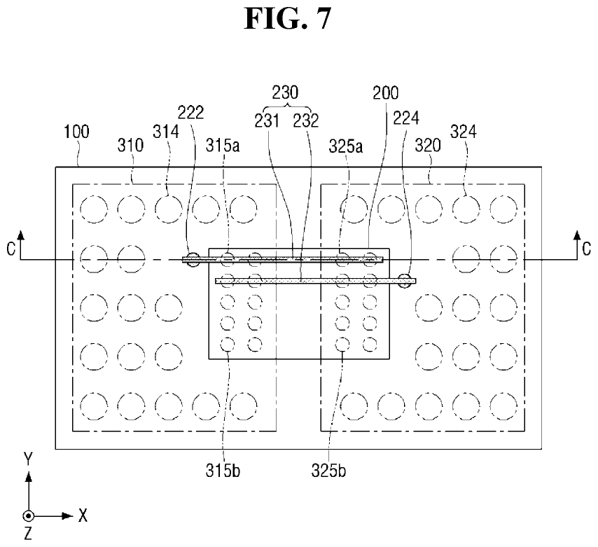

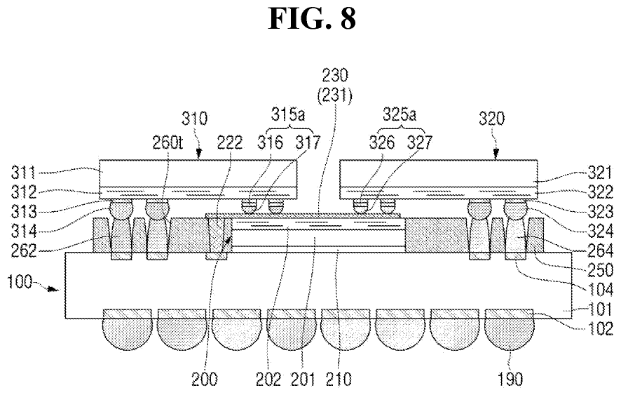

FIG. 7 is another illustrative layout view for describing a semiconductor package according to some example embodiments. FIG. 8 is a schematic cross-sectional view taken along line C-C of FIG. 7. For convenience of explanation, elements that are similar to those described above with reference to FIGS. 1 to 6 may be briefly described or omitted.

Referring to FIGS. 7 and 8, in the semiconductor package according to some example embodiments, the trace pattern 230 includes a first sub-trace 231 and a second sub-trace 232.

The first sub-trace 231 and the second sub-trace 232 may each extend in the first direction X. In addition, the first sub-trace 231 and the second sub-trace 232 may be arranged (e.g., spaced apart) along the second direction Y.

In some example embodiments, each of the first sub-trace 231 and the second sub-trace 232 may be electrically connected to one of the first via pattern 222 and the second via pattern 224. As an example, the first sub-trace 231 may be electrically connected to the first via pattern 222 and may not be electrically connected to the second via pattern 224. In addition, as an example, the second sub-trace 232 may be electrically connected to the second via pattern 224 and may not be electrically connected to the first via pattern 222.

In some example embodiments, each of the first sub-trace 231 and the second sub-trace 232 may be electrically connected to both the first semiconductor chip 310 and the second semiconductor chip 320. As an example, both the first trace connection member 315a and the second trace connection member 325a may be electrically connected to the first sub-trace 231. Through this, the first semiconductor chip 310 and the second semiconductor chip 320 may receive the same power supply voltage.

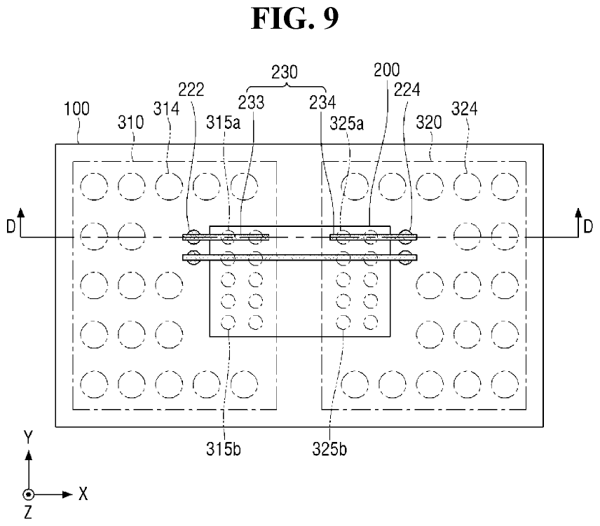

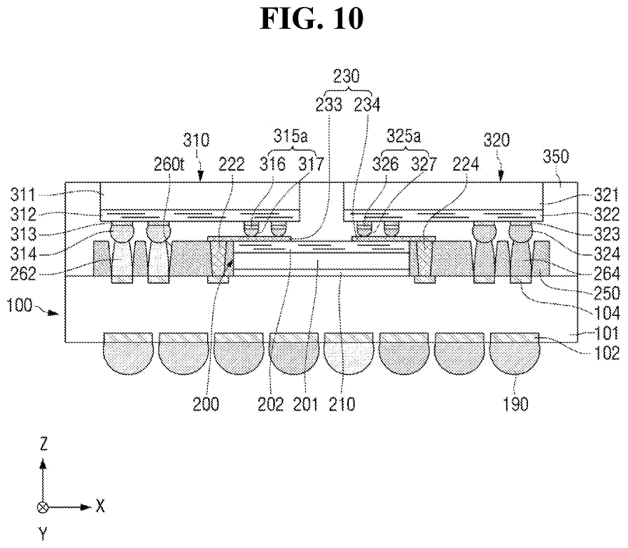

FIG. 9 is another illustrative layout view for describing a semiconductor package according to some example embodiments. FIG. 10 is a schematic cross-sectional view taken along line D-D of FIG. 9. For convenience of explanation, elements that are similar to those described above with reference to FIGS. 1 to 6 may be briefly described or omitted.

Referring to FIGS. 9 and 10, in the semiconductor package according to some example embodiments, the trace pattern 230 includes a third sub-trace 233 and a fourth sub-trace 234.

Each of the third sub-trace 233 and the fourth sub-trace 234 may be electrically connected to one of the first semiconductor chip 310 and the second semiconductor chip 320. As an example, the third sub-trace 233 may electrically connect the first via pattern 222 and the first semiconductor chip 310 to each other, and may not be electrically connected to the second via pattern 224 and the second semiconductor chip 320. In addition, as an example, the fourth sub-trace 234 may electrically connect the second via pattern 224 and the second semiconductor chip 320 to each other, and may not be electrically connected to the first via pattern 222 and the first semiconductor chip 310. Through this, the first semiconductor chip 310 and the second semiconductor chip 320 may receive different power supply voltages.

In some example embodiments, the third sub-trace 233 and the fourth sub-trace 234 may each extend in the first direction X. In some example embodiments, the third sub-trace 233 and the fourth sub-trace 234 may be arranged (e.g., spaced apart) along the first direction X.

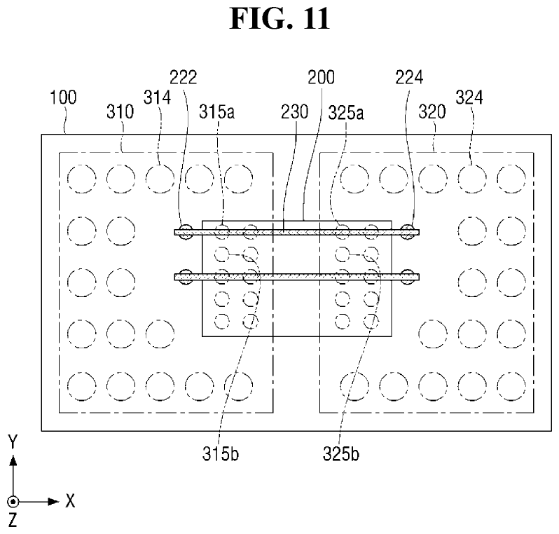

FIGS. 11 to 13 are various illustrative layout views for describing a semiconductor package according to some example embodiments. For convenience of explanation, elements that are similar to those described above with reference to FIGS. 1 to 10 may be briefly described or omitted.

Referring to FIG. 11, in a semiconductor package according to some example embodiments, the first bridge connection member 315a is one of a first plurality of bridge connection members each electrically connecting a bridge pad and a pad of the first chip and/or the second bridge connection member 325b is one of a second plurality of bridge connection members each electrically connecting a bridge pad and a pad of the second chip. At least some of the first plurality of bridge connection members such a bridge connection member 315b and/or at least some of the second plurality of bridge connection members such as bridge connection member 325b may be interposed between traces of the trace pattern 230. For example, as illustrated, bridge connection member 315b and bridge connection member 325b may be interposed between a first trace and a second trace that are adjacent to each other. The first trace and the second trace may be spaced apart from each other by bridge connection member 315b and bridge connection member 325b.

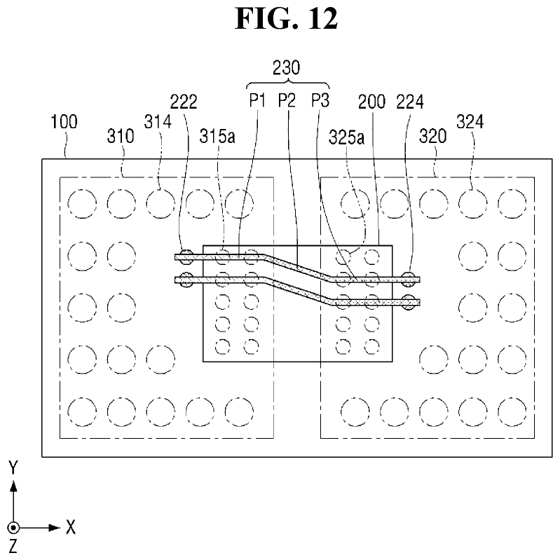

Referring to FIG. 12, in a semiconductor package according to some example embodiments, the trace pattern 230 may be bent or not straight in a plan view. For example, the trace pattern 230 may include a first portion P1, a second portion P2, and a third portion P3. The first portion P1 may extend in the first direction X from the first via pattern 222. The second portion P2 may be bent or angled from the first portion P1 and may extend in a diagonal direction other than the first direction X and the second direction Y. The third portion P3 is bent or angled from the second portion P2 and extends in the first direction X, and may be electrically connected to the second via pattern 224.

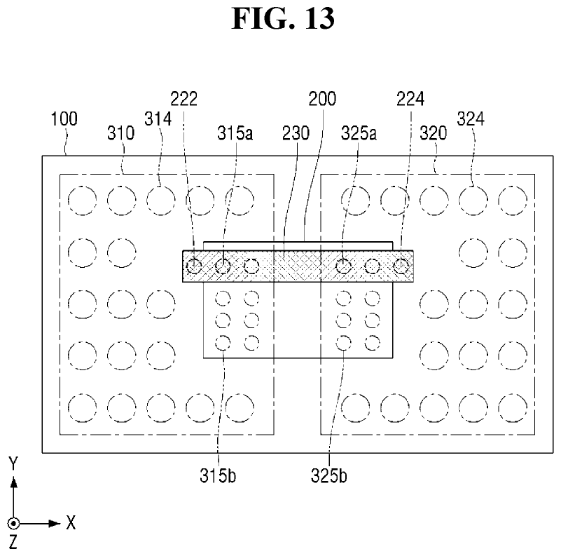

Referring to FIG. 13, in a semiconductor package according to some example embodiments, the trace pattern 230 and/or traces within the trace pattern 230 may have a plate (e.g., flattened) shape. For example, the trace pattern 230 may have a plate shape extending in a plane (e.g., an XY plane) including the first direction X and the second direction Y.

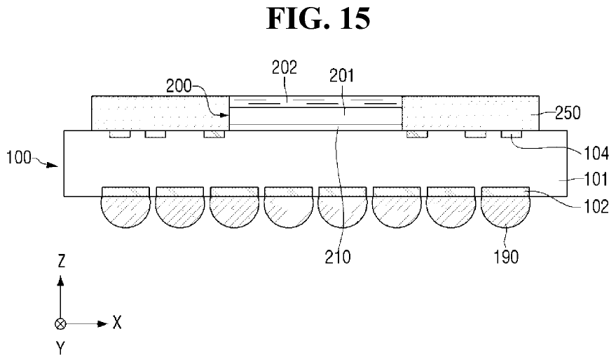

Hereinafter, a method for fabricating a semiconductor package according to example embodiments will be described with reference to FIGS. 1 to 19.

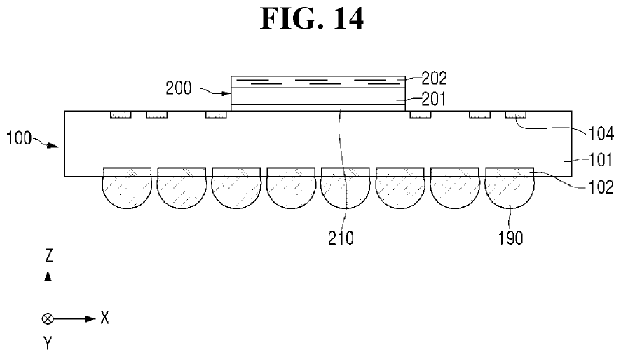

FIGS. 14 to 19 are intermediate step views for describing a method for fabricating a semiconductor package according to some example embodiments. For convenience of explanation, elements that are similar to or the same as those described above with reference to FIGS. 1 to 13 will be briefly described or omitted.

Referring to FIG. 14, a bridge structure 200 is stacked on a package substrate 100.

The package substrate 100 may be a substrate for a semiconductor package. The package substrate 100 may include an insulating core 101, a first substrate pad 102, and a second substrate pad 104.

The bridge structure 200 may include a bridge substrate 201 and a bridge wiring structure 202. The bridge structure 200 may be stacked on an upper surface of the package substrate 100 and secured by, for example, an adhesive film 210.

Referring to process 15, a first molding member 250 is formed or provided on the package substrate 100.

The first molding member 250 may surround a side surface of the bridge structure 200. In addition, the first molding member 250 may expose the upper surface of the bridge structure 200. The first molding member 250 may include, for example, an insulating polymer material such as an epoxy molding compound (EMC), but is not limited thereto.

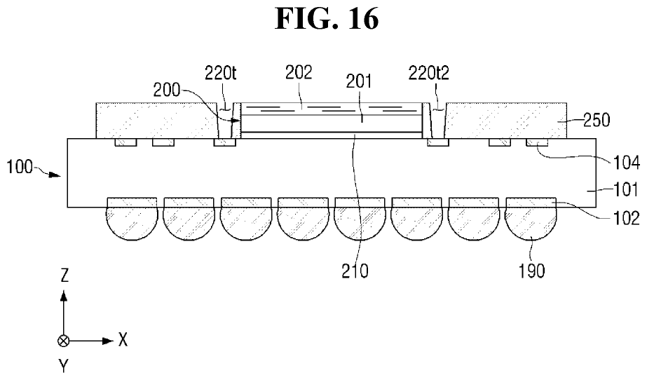

Referring to FIG. 16, a second mold through hole 220t is formed in the first molding member 250. Other mold through holes such as mold through hole 220t2 may be formed in the first molding member 250.

The second mold through hole 220t may extend in the third direction Z within the first molding member 250 to expose the second substrate pad 104. In some example embodiments, a width of the second mold through hole 220t may decrease as a distance from the upper surface of the package substrate 100 decreases. This may be due to characteristics of an etching process performed on the first molding member 250 to form the second mold through hole 220t.

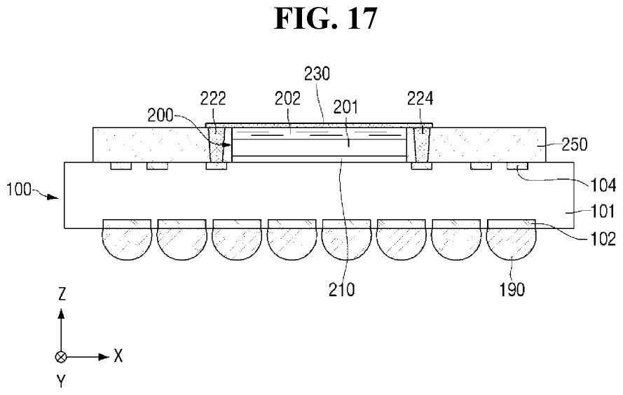

Referring to FIG. 17, a first via pattern 222, a second via pattern 224, and a trace pattern 230 are formed.

The first via pattern 222 and the second via pattern 224 may each fill a mold through hole such as second mold through hole 220t and mold through hole 220t2 of FIG. 16. Through this, the first via pattern 222 and the second via pattern 224 may be each electrically connected to the second substrate pad 104.

Each of the first via pattern 222 and the second via pattern 224 may be formed of and/or include a conductive material such as copper (Cu), aluminum (Al), silver (Ag), tin (Sn), gold (Au), nickel (Ni), lead (Pb), titanium (Ti), or an alloy thereof, but is not limited thereto. In some example embodiments, each of the first via pattern 222 and the second via pattern 224 may be a conductive pattern formed by spraying and curing conductive ink into the second mold through hole 220t of FIG. 16.

The trace pattern 230 may be formed or provided on the bridge structure 200 and the first molding member 250. In addition, the trace pattern 230 may be electrically connected to at least one of the first via pattern 222 and the second via pattern 224.

The trace pattern 230 including the traces may be formed or and/or include a conductive material such as copper (Cu), aluminum (Al), silver (Ag), tin (Sn), gold (Au), nickel (Ni), lead (Pb), titanium (Ti), or an alloy thereof, but is not limited thereto. In some example embodiments, traces of the trace pattern 230 may be formed by a trace-on-mold process. For example, the traces of the trace pattern 230 may be a conductive pattern formed by spraying and curing conductive ink on the upper surface of the bridge structure 200 and the upper surface of the first molding member 250.

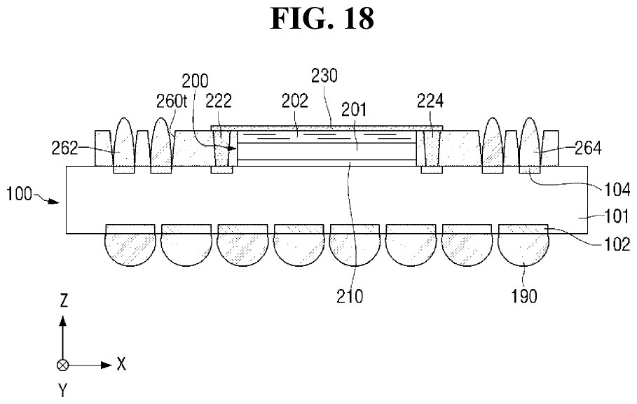

Referring to FIG. 18, a first through via 262 and a second through via 264 are formed or provided in the first molding member 250.

For example, a first mold through hole 260t extending in the third direction Z within the first molding member 250 may be formed to expose the second substrate pad 104. Other mold through holes may be formed. Each of the first through via 262 and the second through via 264 may be formed in a through hole such as the first mold through hole 260t and electrically connected to the second substrate pad 104. In some embodiments, the first mold through hole 260t and other through holes may be mold trenches extending laterally from the third direction Z. The width of a mold trench may decrease as a distance from the package substrate decreases.

Each of the first through via 262 and the second through via 265 may be formed or and/or include a conductive material such as copper (Cu), aluminum (Al), silver (Ag), tin (Sn), gold (Au), nickel (Ni), lead (Pb), titanium (Ti), or an alloy thereof, but is not limited thereto.

In the example embodiment of FIGS. 17 and 18 forming the first through via 262 and the second through via 264 is performed after forming the first via pattern 222 and the second via pattern 224, but this is only an example. As another example, unlike that illustrated, forming the first through via 262 and the second through via 264 may also be performed before forming the first via pattern 222 and the second via pattern 224.

As still another example, unlike that illustrated, forming the first through via 262 and the second through via 264 may also be performed simultaneously with forming the first via pattern 222 and the second via pattern 224. For example, the first via pattern 222, the second via pattern 224, the first through via 262, and the second through via 264 may be formed at the same level. Herein, the term “same level” refers to formation by the same fabricating process and may also refer to the vertical level at which the vias are formed.

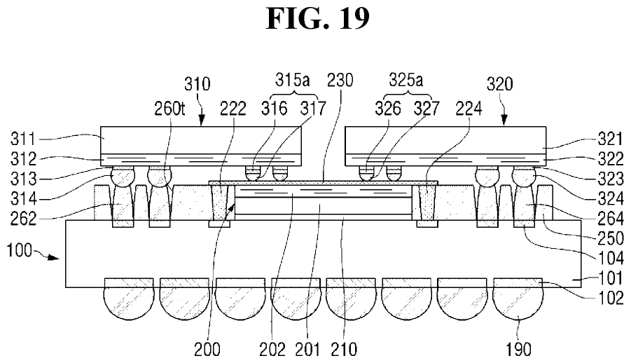

Referring to FIG. 19, a first semiconductor chip 310 and a second semiconductor chip 320 are stacked on the bridge structure 200 and the first molding member 250.

The first semiconductor chip 310 may include a first semiconductor substrate 311 and a first wiring structure 312, and the second semiconductor chip 320 may include a second semiconductor substrate 321 and a second wiring structure 322. In some example embodiments, the first semiconductor chip 310 and the second semiconductor chip 320 may be respectively stacked on the bridge structure 200 and the first molding member 250 and secured by a face-to-face (F2F) bonding manner.

Each of the first semiconductor chip 310 and the second semiconductor chip 320 may overlap the bridge structure 200 and the first molding member 250 in the third direction Z. In addition, at least one of the first semiconductor chip 310 and the second semiconductor chip 320 may overlap the trace pattern 230 in the third direction Z.

The first semiconductor chip 310 may be electrically connected to the package substrate 100 through the first through via 262, and the second semiconductor chip 320 may be electrically connected to the package substrate 100 through the second through via 264. For example, a first chip connection member 314 electrically connecting the first through via 262 and the first chip pad 313 to each other may be formed, and a second chip connection member 324 electrically connecting the second through via 264 and the second chip pad 323 to each other may be formed.

The first semiconductor chip 310 and the second semiconductor chip 320 may be electrically connected to each other through the bridge structure 200. For example, as illustrated in FIGS. 1 and 3, a first bridge connection member 315b electrically connecting the bridge pad 203 and the first chip pad 313 to each other may be formed, and a second bridge connection member 325b electrically connecting the bridge pad 203 and the second chip pad 323 to each other may be formed.

At least one of the first semiconductor chip 310 and the second semiconductor chip 320 may be electrically connected to the trace pattern 230. For example, as illustrated, a first trace connection member 315a electrically connecting a trace of the trace pattern 230 and the first chip pad 313 to each other may be formed. Alternatively, a second trace connection member 325a electrically connecting a trace of the trace pattern 230 and the second chip pad 323 to each other may be formed.

Next, a second molding member 350 is formed which may result in the semiconductor package shown in FIG. 2. The second molding member 350 may cover at least portions of the first molding member 250, the first semiconductor chip 310, and the second semiconductor chip 320. Through this, the semiconductor package described above with reference to FIGS. 1 to 3 may be fabricated.

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. A semiconductor package comprising:
a package substrate;
a bridge structure stacked on the package substrate;
a first molding member on the package substrate and surrounding a side surface of the bridge structure;
a trace pattern extending along an upper surface of the bridge structure and an upper surface of the first molding member;
a first via pattern penetrating through the first molding member and electrically connecting the package substrate and the trace pattern to each other;
a first through via penetrating through the first molding member and spaced apart from a first side surface of the bridge structure;
a second through via penetrating through the first molding member and spaced apart from a second side surface of the bridge structure;
a first semiconductor chip stacked on the trace pattern and the first through via;
a second semiconductor chip stacked on the trace pattern and the second through via;
a first chip connection terminal electrically connecting the first through via and the first semiconductor chip to each other;
a second chip connection terminal electrically connecting the second through via and the second semiconductor chip to each other;
a first trace connection terminal electrically connecting the trace pattern and the first semiconductor chip to each other;
a second trace connection terminal electrically connecting the trace pattern and the second semiconductor chip to each other; and
a second molding member covering at least a portion of the first semiconductor chip and at least a portion of the second semiconductor chip on the package substrate.

2. The semiconductor package of claim 1, further comprising:
a first bridge connection terminal electrically connecting the bridge structure and the first semiconductor chip to each other; and
a second bridge connection terminal electrically connecting the bridge structure and the second semiconductor chip to each other.

3. The semiconductor package of claim 2, wherein a size of the first trace connection terminal and a size of the first bridge connection terminal are each smaller than a size of the first chip connection terminal, and
a size of the second trace connection terminal and a size of the second bridge connection terminal are each smaller than a size of the second chip connection terminal.

4. The semiconductor package of claim 1, wherein the bridge structure includes a bridge substrate and a bridge wiring layer on a front side of the bridge substrate, and
the trace pattern extends along an upper surface of the bridge wiring layer and the upper surface of the first molding member.

5. The semiconductor package of claim 4, wherein the first semiconductor chip includes a first semiconductor substrate and a first wiring layer on a front side of the first semiconductor substrate,
the second semiconductor chip includes a second semiconductor substrate and a second wiring layer on a front side of the second semiconductor substrate, and
the front side of the first semiconductor substrate and the front side of the second semiconductor substrate each face the front side of the bridge substrate.

6. The semiconductor package of claim 1, further comprising a second via pattern penetrating through the first molding member and electrically connecting the package substrate and the trace pattern to each other,
wherein the first via pattern is disposed adjacent the first side surface of the bridge structure, and
the second via pattern is disposed adjacent the second side surface of the bridge structure.

7. The semiconductor package of claim 6, wherein the first via pattern is closer to the bridge structure than the first through via is to the bridge structure, and
The second via pattern is closer to the bridge structure than the second through via is to the bridge structure.

8. The semiconductor package of claim 1, further comprising an adhesive film interposed between the package substrate and the bridge structure.

9. The semiconductor package of claim 1, wherein the first semiconductor chip is an application processor chip or a logic chip, and
the second semiconductor chip is a memory chip.

10. The semiconductor package of claim 9, wherein the second semiconductor chip includes a high bandwidth memory (HBM).

11. A semiconductor package comprising:
a package substrate;
a bridge structure stacked on the package substrate;
a first molding member on the package substrate and surrounding a side surface of the bridge structure;
a trace pattern extending along an upper surface of the bridge structure and an upper surface of the first molding member;
a via pattern penetrating through the first molding member and electrically connecting the package substrate and the trace pattern to each other;
a first semiconductor chip and a second semiconductor chip each stacked on an upper surface of the first molding member and electrically connected to each other by the bridge structure;
a first through via penetrating through the first molding member and electrically connecting the package substrate and the first semiconductor chip to each other;
a second through via penetrating through the first molding member and electrically connecting the package substrate and the second semiconductor chip to each other;
a first trace connection terminal electrically connecting the trace pattern and the first semiconductor chip to each other; and
a second trace connection terminal electrically connecting the trace pattern and the second semiconductor chip to each other.

12. The semiconductor package of claim 11, wherein the semiconductor package is configured to receive a power supply voltage and transfer the power supply voltage to the first semiconductor chip and the second semiconductor chip, respectively, through the package substrate, the via pattern, and the trace pattern.

13. The semiconductor package of claim 11, wherein a width of the via pattern decreases as a distance from the package substrate decreases.

14. The semiconductor package of claim 11, wherein the first molding member includes a plurality of mold trenches exposing an upper surface of the package substrate, and
each of the first through via and the second through via are disposed in a respective mold trench of the plurality of mold trenches and are connected to the package substrate.

15. The semiconductor package of claim 14, wherein a width of each of the plurality of mold trenches decreases as a distance from the package substrate decreases.

16. The semiconductor package of claim 11, further comprising a second molding member covering at least a portion of the first semiconductor chip and at least a portion of the second semiconductor chip on the package substrate.

17. A semiconductor package comprising:
a package substrate;
a bridge structure stacked on the package substrate;
a first molding member surrounding a side surface of the bridge structure;
a trace pattern extending along an upper surface of the bridge structure and an upper surface of the first molding member;
a via pattern penetrating through the first molding member and electrically connecting the package substrate and the trace pattern to each other; and
a first semiconductor chip and a second semiconductor chip each stacked on the upper surface of the first molding member and electrically connected to each other by the bridge structure,
wherein the first semiconductor chip and the second semiconductor chip are arranged along a first direction parallel to an upper surface of the package substrate, and
the trace pattern extends in the first direction and is electrically connected to at least one of the first semiconductor chip and the second semiconductor chip.

18. The semiconductor package of claim 17, wherein the trace pattern is formed from conductive ink.

19. The semiconductor package of claim 17, wherein the semiconductor package is configured to receive a power supply voltage and transfer the power supply voltage to the first semiconductor chip and the second semiconductor chip, respectively, through the package substrate, the via pattern, and the trace pattern.

20. The semiconductor package of claim 17, further comprising a second molding member covering at least a portion of the first semiconductor chip and at least a portion of the second semiconductor chip on the package substrate.
